(19) United States
(12) Patent Application Publication
(10) Pub. No.: US 2012/0204946 A1
(43) Pub. Date: Aug. 16, 2012

(54) METHOD FOR PRODUCING AN EMITTER ELECTRODE FOR A CRYSTALLINE SILICON SOLAR CELL AND CORRESPONDING SILICON SOLAR CELL

(75) Inventors: Helge Haverkamp, Herrenberg (DE); Petra Mitzinneck, Karlsruhe (DE); Kay Kieninger, Weiler (DE); Jurgen Sollner, Wangen (DE)

(73) Assignee: GEBR. SCHMID GMBH, Freudenstadt (DE)

(21) Appl. No.: 13/371,139

(22) Filed: Feb. 10, 2012

Related U.S. Application Data
(63) Continuation of application No. PCT/EP2010/061797, filed on Aug. 12, 2010.

(30) Foreign Application Priority Data
Aug. 13, 2009 (DE) 10 2009 038 141.4

(51) Int. Cl. H01L 31/0224; H01L 31/18

(52) U.S. Cl. 136/256; 438/98; 257/E31.124

(57) ABSTRACT

In a method for producing a front-side emitter electrode as front contact for a silicon solar cell on a silicon wafer, a depression is produced in the front side of said silicon wafer. A front-side n-doped silicon layer and an antireflection layer are then produced. A paste is then introduced into the depression, said paste containing electrically conductive metal particles and etching glass frit. Said paste, as a result of momentary heating, etches through the antireflection layer to the n-doped silicon layer making electrical contact with the latter. Afterwards, electrically conductive front contact metal is galvanically attached as front contact onto the heat-treated paste in the depression.

### CROSS-REFERENCE TO RELATED APPLICATIONS

This application is a continuation of PCT Application No. PCT/EP2010/061797, filed Aug. 12, 2010, and claims priority to DE 10 2009 038 141.4 filed Aug. 13, 2009, the disclosures of which are hereby incorporated by reference in their entirety.

### FIELD OF APPLICATION AND PRIOR ART

The invention relates to a method for producing a front-side emitter electrode as front contact for a crystalline silicon solar cell on a silicon wafer, and to a silicon solar cell produced by such a method.

In order to produce a front contact on a crystalline silicon solar cell, a conductor track is usually printed onto a front-side n-doped silicon layer with an antireflection layer thereon, by means of screen printing. At the present time, said conductor track can be printed with a width of approximately 120 μm to 150 μm with the result that the front contact has approximately this width. With this width it then also screens the solar cell, which has a significant and negative effect given the customary number of front contacts overall. At the present time, the production of narrower conductor tracks by means of screen printing is technically possible only with very great difficulty since screen printing methods have a certain limited resolution and narrow conductor tracks can therefore be applied only with very great difficulty. In order to reduce the shading of the front-side emitter electrode of a crystalline silicon solar cell and thus to increase the efficiency, it could admittedly be attempted nevertheless to reduce even further the structure width of the conductor tracks for the emitter electrode during the screen printing methods mentioned. However, this has the disadvantageous effect that reducing their width without simultaneously increasing the height is accompanied by a reduction in the cross-sectional area. This in turn results in a lower conductivity, as a result of which the electrical losses with regard to the series resistance increase.

### OBJECT AND HOW IT IS ACHIEVED

It is an object of the invention to provide a method as mentioned in the introduction and a silicon solar cell produced thereby with which problems in the prior art can be avoided and, in particular, front contacts can be produced, which are as narrow as possible.

This object is achieved by means of a method comprising the features of claim 1 and also a silicon solar cell comprising the features of claim 15. Advantageous and preferred configurations of the invention are the subject matter of the further claims and are explained in greater detail below. In this case, some of the features enumerated below are mentioned only for the method or only for the silicon solar cell. However, irrespective of this they are intended to be applicable both to the method and to the silicon solar cell. The wording of the claims is incorporated by explicit reference in the content of the description.

It is provided that a depression for the front contact is produced in the front side of the silicon wafer. Afterwards, a front-side n-doped silicon layer is produced in a known manner and a customary antireflection layer is applied thereto. The depression can therefore have the form that is intended subsequently to predefine the form for the front contact, in particular therefore as an elongated narrow line. Afterwards, a paste is introduced into the depression, said paste containing electrically conductive metal particles and etching glass frit. Said paste is then momentarily heated or heat-treated, in particular for a few seconds, which can be effected for example at a temperature of approximately 800° C. As a result, the paste, in particular by virtue of the glass frit, etches through the antireflection layer as far as the n-doped silicon layer and can make electrical contact with the latter by means of the metal particles. In a further step, the front contact metal is then galvanically attached or applied onto the heat-treated paste, or the electrically conductive layer formed thereby, in the depression. The thickness of the front contact metal is then advantageously significantly higher than that of the heat-treated paste, or the electrically conductive layer formed thereby, such that this front contact metal as front contact or front-side emitter electrode then undertakes the actual task of the electrical conductivity.

The advantage of this method is that by means of the depression, which is advantageously embodied as a type of trench, or the width of said depression, the width of the front contact that then arises can be predefined. If the depression is produced with a width of between 50 μm and 100 μm, advantageously 60 μm to 80 μm, then this is actually also the maximum width of the front contact that arises. Therefore under certain circumstances, it can be half as wide as hitherto. This actually results in considerably less shading than hitherto. A depression can be produced with a depth of 15 μm to 40 μm, for example, so that their width is larger than their depth.

Specifically, one effect of the depression is, moreover, that the paste, if it is of rather low viscosity, cannot run arbitrarily as in the case of screen printing on a planar area. As a result, even pastes of very low viscosity or inks can be used. This in turn simplifies the application of the paste or ink, which advantageously is done by means of an inkjet method using a so-called inkjet printing device that is per se well-known to a person skilled in the art. This can in particular be done with a relatively high accuracy or high resolution into the narrow depressions or trenches. With a screen printing procedure, said effect may in general not be achieved in such quality and mainly failure-free over extended times without clogging of screens and as a result frequent need of maintenance.

The paste or ink, which can be per se a type of standard paste for such electrically conductive contact-connection, can contain nanoparticles comprising silver as electrically conductive particles. This can be, for example silver provided with a thin coating. Said nanoparticles can make up approximately 30% to 70% of the solids proportion of the paste or ink, advantageously approximately 40% to 60% or approximately half.

The etching glass frit in the paste can be embodied as usual, for example with lead oxide and/or cadmium oxide.

The depression can, on the one hand, be produced mechanically by scribing or the like. However, laser action has proved to be advantageous, which operates rapidly and precisely and produces depressions having the desired dimensions.

The depression does not have to be completely filled by the front contact metal; in particular, care should even be taken to avoid totally filling said depression. This is because if a certain amount of front contact metal should then additionally be attached virtually beyond the depression, there is the risk that it would be attached with a customary attachment characteristic with a width beyond the depressions. The shading would then in turn become undesirably great. For this reason, it is also considered to be sufficient for the depression to be only approximately half filled, possibly also to a somewhat greater extent. A finished metallic front contact of the silicon solar cell can then have a height of approximately 10 μm to 20 μm, which results in a sufficient electrical conductivity.

An abovementioned method for introducing the paste can ensure that the latter is actually only introduced into the depression. Undesired shading can thus also be reduced or avoided.

During the galvanic attachment or application of the front contact metal, a plurality of metals can be applied, to be precise in a specific temporal sequence. It has proved to be advantageous firstly to apply nickel as a diffusion barrier in order to prevent subsequently applied copper, which principally undertakes the electrical conductivity of the subsequent front contact, from indiffusing into the silicon. This is very important since such indiffusion of copper poisons, as it were, the silicon or the semiconductor properties thereof. Finally, tin can be applied in order to prevent oxidation of the copper. In this case, it may be provided that the proportion of applied copper is considerably greater than that of the other metals. The abovementioned three steps of the galvanic application of metals for the front contact can be carried out in succession in continuous installations. In this case, it is possible to assist this application or the electrodeposition with light or to illuminate the silicon wafers in the process. This reduces the current intensity to be introduced and applied. In this respect, reference is made to EP 542 148 A1, which explains this technique.

These and further features emerge not only from the claims but also from the description and the drawings, wherein the individual features can be realized in each case by themselves or as a plurality in the form of subcombinations in an embodiment of the invention and in other fields and can constitute advantageous and inherently protectable embodiments for which protection is claimed here. The subdivision of the application into individual sections and sub-headings do not restrict the general validity of the statements made thereunder.

### BRIEF DESCRIPTION OF THE DRAWINGS

An exemplary embodiment of the invention is illustrated schematically in the drawings and is explained in greater detail below. In the drawings:

FIGS. 1 to 5 show different processing steps of a silicon wafer for producing a front contact.

### DETAILED DESCRIPTION OF THE EXEMPLARY EMBODIMENT

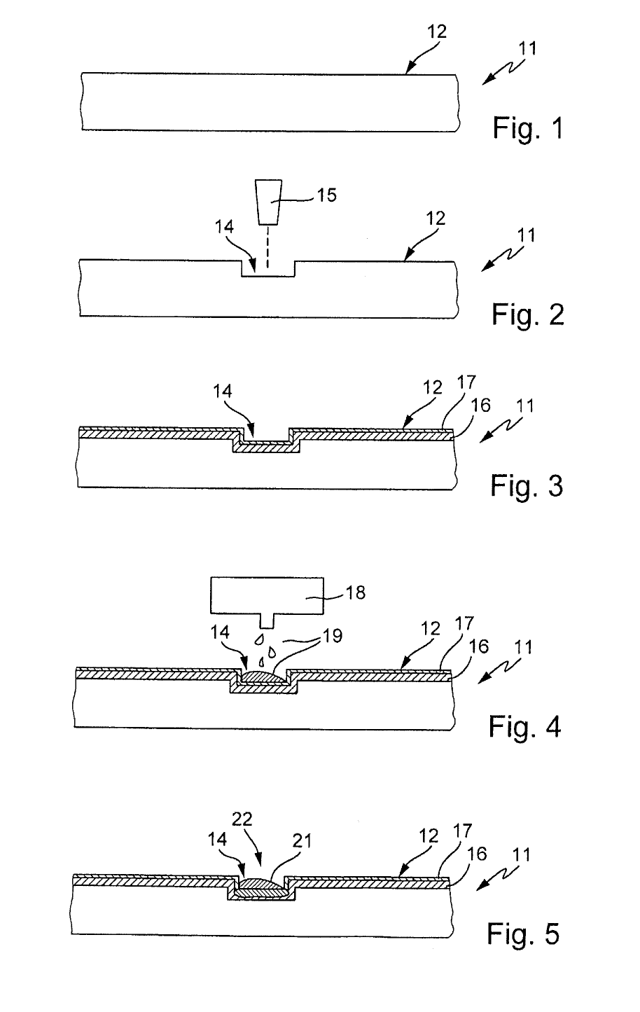

FIG. 1 illustrates a crystalline silicon wafer 11 in lateral section. Said wafer has a front side 12 facing upwards. The wafer is intended to be processed to form a silicon solar cell.

In accordance with FIG. 2, a depression 14 in the manner of a trench is introduced into the front side 12 by means of a laser 15. The depression 14 can have a width of 60 μm to 80 μm and a depth of 20 μm to 30 μm. The specific embodiment of the depression 14 is not always completely rectangular as illustrated here, but that is not a disturbance. What is actually important is that a depression or a type of trench is produced.

In a further step in accordance with FIG. 3, an n-doped silicon layer 16 is produced on the front side 12 in a known manner. A customary antireflection layer 17 is applied thereon in a known manner. These two layers then actually also have the depression 14, or the depression 14 is still present.

In yet another step in accordance with FIG. 4, a previously described paste 19 is introduced into the depression 14 by means of an inkjet printer 18. Such inkjet printers 18 are known in the art and need not be explained in any further detail. The paste 19 can be formed with a composition according to criteria mentioned above and comprises nanoparticles comprising silver as solids proportion, for example approximately 50% by weight of the solids proportion. Furthermore the paste additionally comprises etching glass frit, in particular lead or cadmium oxide, which is also known per se however. The amount of applied paste 19 in the depression 14 can vary. The amount of paste 19 present should be enough for it to etch through the antireflection layer 17 by means of the glass frit and to make contact with the n-doped silicon layer or penetrate into the latter during the subsequent step (not illustrated) of the heat treatment or sintering with parameters mentioned above. This can proceed even further than illustrated here. Furthermore, there should be a metallically or electrically conductive connection between the n-doped layer 16 and the surface of the heat-treated paste 19, which advantageously extends over the substantial or entire width of the depression 14, such that a front contact can subsequently be produced.

FIG. 5 then illustrates how front contact metal 21 has been applied galvanically, advantageously by means of assistance by illumination in the manner described above. This front contact metal 21 is significantly thicker than the paste 19 and, on account of its composition, also has very much better electrical conductivity. It can be attached very well on the conductive layer formed by the heat-treated paste. The front contact metal 21 can consist of or comprise the above-described metals nickel, copper and tin, which are then applied successively in three galvanic steps.

The front contact 22 thereby formed overall can approximately half fill the depression 14, but possibly also to a somewhat greater extent. Care should merely be taken to ensure that the front contact metal 21 does not reach the planar front side 12 and spread there. Firstly, copper could in turn pass into the silicon, which should be avoided for reasons mentioned above. Furthermore, shading of the front side 12 of a crystalline silicon solar cell fabricated from the silicon wafer 11 would then in turn increase since more than the width of the depression is actually covered.

1. A method for producing a front-side emitter electrode as front contact for a crystalline silicon solar cell on a silicon wafer, said silicon wafer having a front side and a back side, the method comprising the steps of:
producing a depression for said front contact in said front side and, after an n-doped silicon layer has been produced on said front-side and an antireflection layer has been applied onto said front-side, introducing a paste into said depression, said paste containing electrically conductive metal particles and etching glass frit,
wherein said paste, after momentary heating or heat treatment, then etches through said antireflection layer to said n-doped silicon layer and makes electrical contact with said n-doped silicon layer, wherein an electrically conductive front contact metal is then galvanically attached or applied onto said heat-treated paste in said depression.

2. The method according to claim 1, wherein during the galvanically attaching or applying of said front contact metal, a plurality of metals are applied in a specific sequence.

3. The method according to claim 2, wherein firstly nickel is applied as a diffusion barrier in order to prevent a subsequently applied copper from diffusing into said silicon wafer, wherein subsequently copper is applied, and finally tin for preventing an oxidation of said copper is applied.

4. The method according to claim 1, wherein said metal particles in said paste comprise nanoparticles comprising silver.

5. The method according to claim 4, wherein said silver has a proportion of 30% to 70% of the solids proportion of said paste.

6. The method according to claim 1, wherein said depression is filled by said front contact metal at least to an extent of 30%.

7. The method according to claim 6, wherein said depression is filled by said front contact metal at least to an extent of approximately 50% to 60%.

8. The method according to claim 1, wherein said depression is produced by laser action.

9. The method according to claim 1, wherein said depression is produced with a width of between 50 μm and 100 μm.

10. The method according to claim 1, wherein said depression is produced with a depth of 15 μm to 40 μm.

11. The method according to claim 1, wherein said paste is introduced into said depression by means of an inkjet method.

12. The method according to claim 1, wherein said attachment or application of said front contact with said front contact metal onto said heat-treated paste is effected by means of a light-induced electroplating or a light-assisted electroplating.

13. The method according to claim 1, wherein said paste is introduced solely into said depression.

14. The method according to claim 1, wherein said depression is produced as a trench with a width larger than a depth.

15. A silicon solar cell, produced according to a method according to claim 1, wherein said depression is approximately half filled with said front contact metal.

16. The silicon solar cell according to claim 15, wherein a finished metallic front contact of said silicon solar cell has a width corresponding to said depression of approximately 60 μm to 80 μm and a height of approximately 10 μm to 20 μm.
